(19) United States
(12) Patent Application Publication
(10) Pub. No.: US 2025/0203995 A1
(43) Pub. Date: Jun. 19, 2025

(54) METHOD OF MANUFACTURING SEMICONDUCTOR DEVICE

(71) Applicant: Renesas Electronics Corporation, Tokyo (JP)

(72) Inventors: Tomoki AYANO, Tokyo (JP); Takahiro MARUYAMA, Tokyo (JP)

(21) Appl. No.: 18/931,213

(22) Filed: Oct. 30, 2024

(30) Foreign Application Priority Data
Dec. 18, 2023 (JP) 2023-213008

(51) Int. Cl. H01L 29/40; H01L 21/285; H01L 21/311; H01L 21/3213

(52) U.S. Cl. CPC H10D 64/117; H01L 21/28556; H01L 21/31116; H01L 21/32136

(57) ABSTRACT

Reliability of a semiconductor device is improved. An insulating film is formed in an inner portion of a trench and on an upper surface of a semiconductor substrate. A field plate electrode is formed on the insulating film to fill the inner portion of the trench. The field plate electrode is recessed toward a bottom portion of the trench by etching process. Etching process using mixed gas containing CF₄ gas and O₂ gas is performed to an upper surface of the field plate electrode. A silicon oxide film is formed on the upper surface of the field plate electrode by thermal oxidation process.

### CROSS-REFERENCE TO RELATED APPLICATION

The disclosure of Japanese Patent Application No. 2023-213008 filed on Dec. 18, 2023, including the specification, drawings and abstract is incorporated herein by reference in its entirety.

### BACKGROUND

The present invention relates to a method of manufacturing a semiconductor device, and relates to, for example, a method of manufacturing a semiconductor device including a gate electrode and a field plate electrode in an inner portion of a trench.

A semiconductor device including a semiconductor element such as a power MOSFET (metal oxide semiconductor field effect transistor) adopts a trench gate structure in which a gate electrode is embedded in an inner portion of a trench. As one type of the trench gate structure, a split gate structure in which a field plate electrode is formed in a lower portion of a trench while a gate electrode is formed in an upper portion of the trench is known. A source potential is supplied from a source electrode to the field plate electrode. A depletion layer is spread to a drift region by the field plate electrode, thereby making it possible to increase a concentration of the drift region and to reduce a resistance of the drift region.

There is disclosed a technique listed below.
[Patent Document 1] Japanese Unexamined Patent Application Publication No. 2011-199109

For example, the Patent Document 1 discloses the MOSFET having the split gate structure. A field plate electrode and a gate electrode in the Patent Document 1 are formed as follows. First, a field plate electrode is formed in an inner portion of a trench, and an upper surface of the field plate electrode is then recessed. Then, by thermal oxidation process, a gate insulating film is formed in the inner portion of the trench, and an insulating film is formed on the upper surface of the field plate electrode. Then, a gate electrode is formed on the field plate electrode to fill the inner portion of the trench.

### SUMMARY

A portion of the field plate electrode may be formed in an inner portion of a trench to have a protrusion shape. Existence of such a portion causes problems in which an electric field tends to concentrate, thereby deteriorating a withstand voltage between a gate electrode and a field plate electrode and easily generating a leak current. Accordingly, a technique capable of ensuring the withstand voltage between the gate electrode and the field plate electrode to improve reliability a of semiconductor device has been required.

Other problems and novel characteristics will be apparent from the description of this specification and the accompanying drawings.

The outline of the typical aspects of the embodiments disclosed in the present application will be briefly described as follows.

A method of manufacturing a semiconductor device according to one embodiment includes step (a) of preparing a semiconductor substrate having an upper surface and a lower surface, a step (b) of forming a trench in the semiconductor substrate to reach a predetermined depth from the upper surface of the semiconductor substrate toward the lower surface of the semiconductor substrate after the step (a), a step (c) of forming a first insulating film in an inner portion of the trench and on the upper surface of the semiconductor substrate after the step (b), a step (d) of forming a field plate electrode on the first insulating film to fill the inner portion of the trench after the step (c), a step (e) of recessing the field plate electrode toward a bottom portion of the trench by etching process after the step (d), a step (f) of performing etching process to an upper surface of the field plate electrode while using mixed gas containing CF₄ gas and O₂ gas after the step (e), and a step (g) of forming a first silicon oxide film on the upper surface of the field plate electrode by first thermal oxidation process after the step (f).

According to one embodiment, the reliability of the semiconductor device can be improved.

### BRIEF DESCRIPTIONS OF THE DRAWINGS

FIG. 1 is a plan view illustrating a semiconductor device according to a first embodiment;

FIG. 2 is a plan view illustrating the semiconductor device according to the first embodiment;

FIG. 3 is a plan view of a principal part illustrating the semiconductor device according to the first embodiment;

FIG. 4 is a plan view of a principal part illustrating the semiconductor device according to the first embodiment;

FIG. 5 is a cross-sectional view illustrating the semiconductor device according to the first embodiment;

FIG. 6 is a cross-sectional view illustrating a step of manufacturing the semiconductor device according to the first embodiment;

FIG. 7 is a cross-sectional view illustrating a manufacturing step continued from the step illustrated in FIG. 6;

FIG. 8 is a cross-sectional view illustrating a manufacturing step continued from the step illustrated in FIG. 7;

FIG. 9 is a cross-sectional view illustrating a manufacturing step continued from the step illustrated in FIG. 8;

FIG. 10 is a cross-sectional view illustrating a manufacturing step continued from the step illustrated in FIG. 9;

FIG. 11 is a cross-sectional view illustrating a manufacturing step continued from the step illustrated in FIG. 10;

FIG. 12 is a cross-sectional view illustrating a manufacturing step continued from the step illustrated in FIG. 11;

FIG. 13 is a cross-sectional view illustrating a manufacturing step continued from the step illustrated in FIG. 12;

FIG. 14 is a cross-sectional view illustrating a manufacturing step continued from the step illustrated in FIG. 13;

FIG. 15 is a cross-sectional view illustrating a manufacturing step continued from the step illustrated in FIG. 14;

FIG. 16 is a cross-sectional view illustrating a manufacturing step continued from the step illustrated in FIG. 15;

FIG. 17 is a cross-sectional view illustrating a manufacturing step continued from the step illustrated in FIG. 16;

FIG. 18 is a cross-sectional view illustrating a manufacturing step continued from the step illustrated in FIG. 17;

FIG. 19 is a cross-sectional view illustrating a manufacturing step continued from the step illustrated in FIG. 18;

FIG. 20 is a cross-sectional view illustrating a manufacturing step continued from the step illustrated in FIG. 19;

FIG. 21 is a cross-sectional view illustrating a manufacturing step continued from the step illustrated in FIG. 20;

FIG. 22 is a cross-sectional view illustrating a manufacturing step continued from the step illustrated in FIG. 21;

FIG. 23 is a cross-sectional view of a principal part illustrating a step of manufacturing a semiconductor device in a first examined example;

FIG. 24 is a principal-part sectional view illustrating a step of manufacturing a semiconductor device in a second examined example;

FIG. 25 is a principal-part perspective view illustrating a step of manufacturing the semiconductor devices in the first embodiment and the second examined example;

FIG. 26 is a cross-sectional view of a principal part illustrating a step of manufacturing the semiconductor device according to the first embodiment; and

FIG. 27 is a cross-sectional view of a principal part illustrating a step of manufacturing a semiconductor device in a modification example.

### DETAILED DESCRIPTION

Hereinafter, embodiments will be described in detail with reference to the accompanying drawings. Note that components having the same function are denoted by the same reference symbols throughout all the drawings for describing the embodiments, and the repetitive description thereof will be omitted. In addition, the description of the same or similar portions is not repeated in principle unless otherwise particularly required in the following embodiments.

An X-direction, a Y-direction, and a Z-direction described in the present application intersect one another and perpendicular to one another. In the present application, the Z-direction is described as an up-down direction, a height direction, or a thickness direction of a structure. An expression such as “plan view” or “planar view” used in the present application means that a surface made of the X-direction and the Y-direction is referred to as a “plane” viewed in the Z-direction.

### First Embodiment

### <Structure of Semiconductor Device>

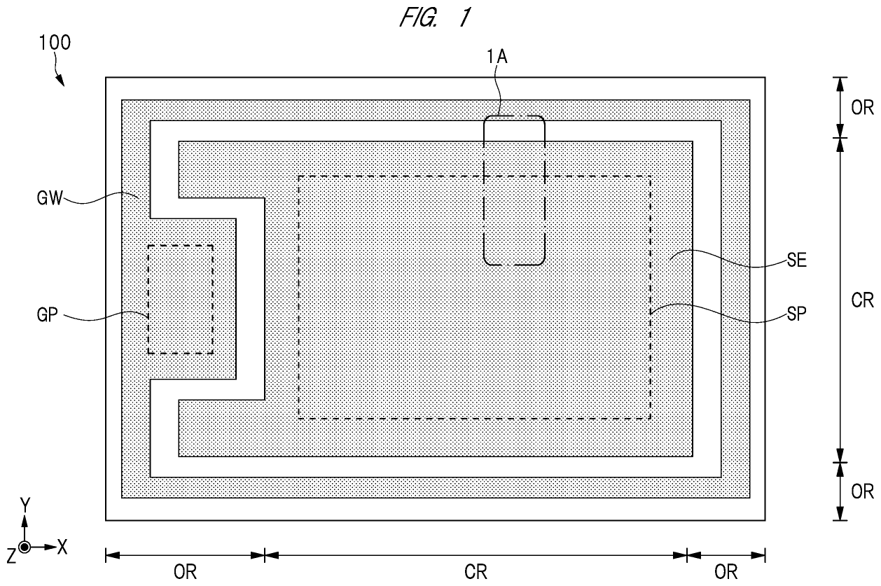

A semiconductor device 100 according to a first embodiment will be described below with reference to FIGS. 1 to 5. The semiconductor device 100 includes a MOSFET having a trench gate structure as a semiconductor element. The MOSFET in the first embodiment forms a split gate structure including a gate electrode GE and a field plate electrode FP.

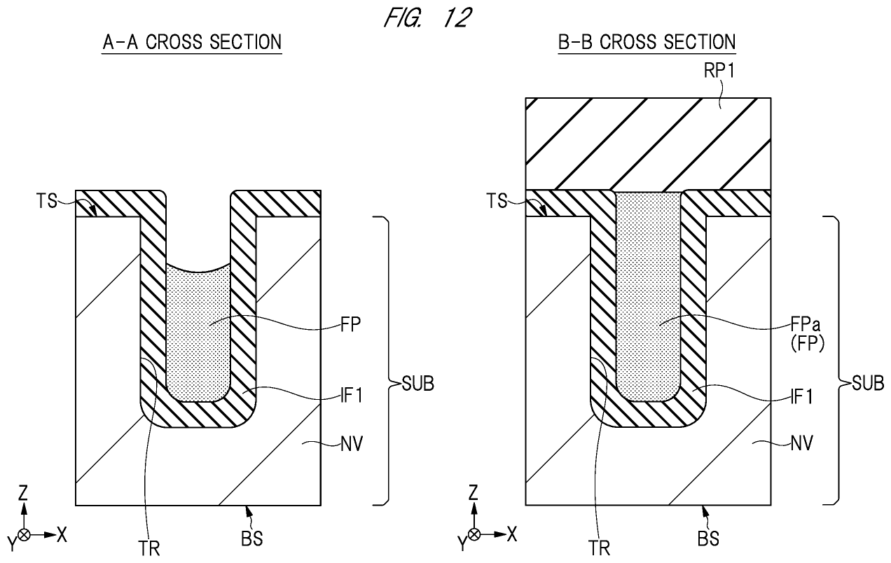

Although main features of the first embodiment include a manufacturing step for performing etching process using mixed gas containing CF₄ gas and O₂ gas to an upper surface of the field plate electrode FP and previous and subsequent manufacturing steps in FIG. 12, details of the features will be described after description of a “method of manufacturing a semiconductor device” described below.

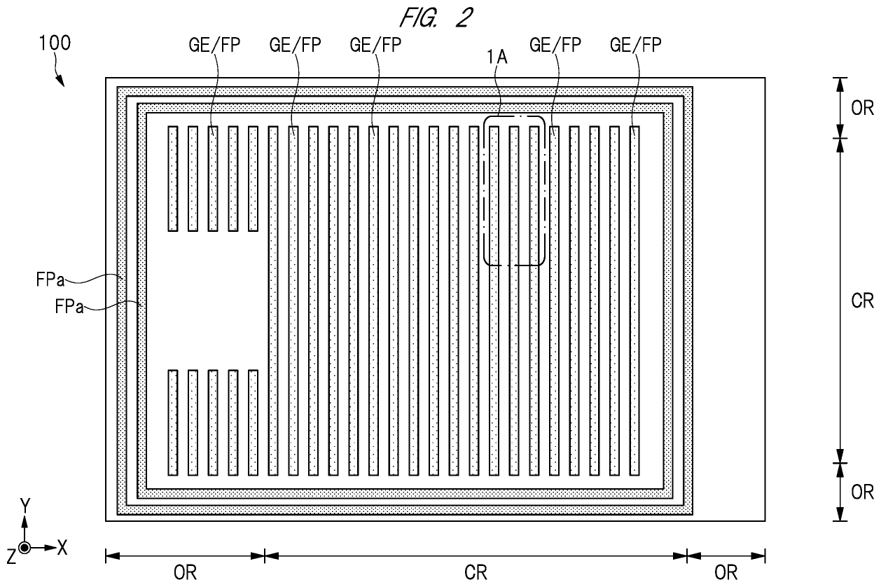

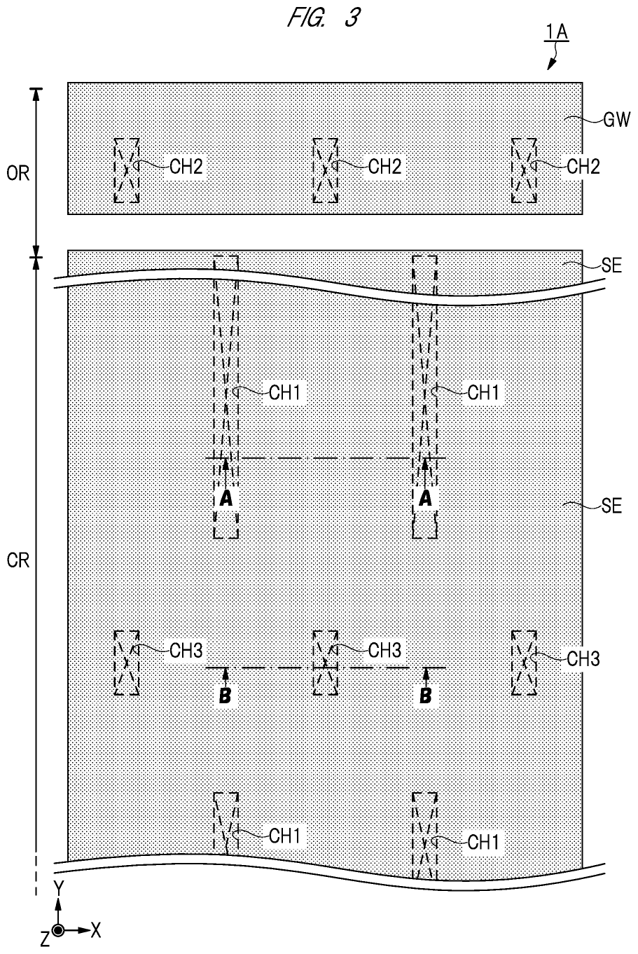

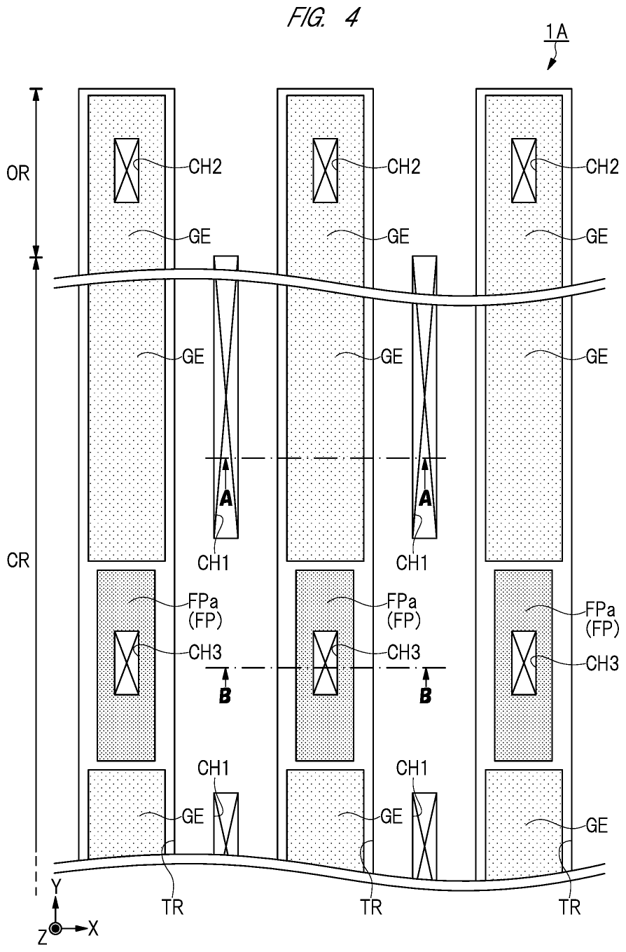

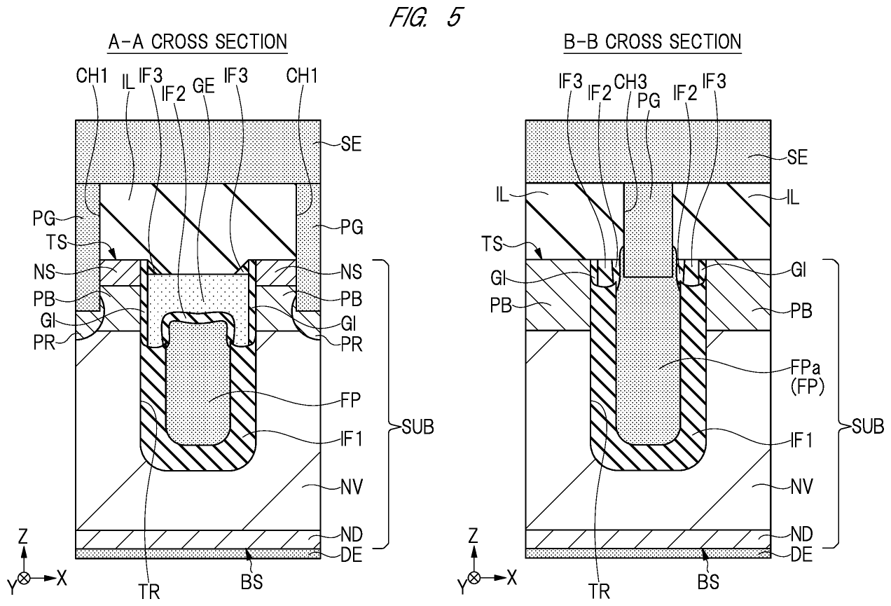

Each of FIGS. 1 and 2 is a plan view of a semiconductor chip as the semiconductor device 100. Each of FIGS. 3 and 4 is a plan view of a principal part illustrating a region 1A illustrated in FIGS. 1 and 2 to be enlarged. FIGS. 2 and 4 respectively illustrate structures below FIGS. 1 and 3, and each mainly illustrate the trench gate structure formed in the semiconductor substrate SUB. Positions of holes CH1, CH2, and CH3 illustrated with broken lines in FIG. 3 respectively coincide with positions of the holes CH1, CH2, and CH3 illustrated in FIG. 4. FIG. 5 is a cross-sectional view illustrating respective cross sections along a line A-A and a line B-B illustrated in each of FIGS. 3 and 4.

FIG. 1 mainly illustrates a wiring pattern formed above the semiconductor substrate SUB. The semiconductor device 100 includes a cell region CR and an outer peripheral region OR surrounding the cell region CR in plan view. A plurality of main semiconductor elements such as MOSFETs are formed in the cell region CR. The outer peripheral region OR is used for, for example, connecting a gate wiring GW to the gate electrode GE and functioning as a termination region.

As illustrated in FIGS. 1 and 2, most of the cell region CR is covered with a source electrode SE. The gate wiring GW surrounds the source electrode SE in plan view. The source electrode SE and the gate electrode GW are covered with a protective film such as a polyimide film, although not illustrated. A portion of the protective film is provided with an opening, and the source electrode SE and the gate wiring GW exposed in the opening respectively serve as a source pad SP and a gate pad GP. When an external connection member is connected onto the source pad SP and the gate pad GP, the semiconductor device 100 is electrically connected to another semiconductor chip, lead frame, wiring board, or the like. The external connection member is, for example, a wire made of aluminum, gold, or copper, or a clip made of a copper plate.

As illustrated in FIG. 4, a plurality of trenches TR are formed in the semiconductor substrate SUB in the cell region CR. The plurality of trenches TR are formed in a stripe pattern, and respectively extend in the Y-direction and are adjacent to one another in the X-direction.

As also illustrated in a cross section A-A in FIG. 5, in the inner portion of the trench TR, the field plate electrode FP is formed in a lower portion of the trench TR, and the gate electrode GE is formed in an upper portion of the trench TR. The field plate electrode FP and the gate electrode GE extend along the trench TR in the Y-direction.

As also illustrated in a cross section B-B in FIG. 5, a portion of the field plate electrode FP in the cell region CR forms a pullout part FPa. The field plate electrode FP forming the pullout part FPa is formed in not only the lower portion of the trench TR but also the upper portion of the trench TR in the inner portion of the trench TR.

As illustrated in FIG. 2, the plurality of trenches TR formed in the outer peripheral region OR extend in the Y-direction and the X-direction to surround the cell region CR in plan view. The field plate electrode FP forming the pullout part FPa is formed in the inner portion of the trench TR in the outer peripheral region OR.

In the cell region CR, the hole CH3 is formed on the pullout part FPa. The pullout part FPa is electrically connected to the source electrode SE via the hole CH3. In the cell region CR, the hole CH1 is formed on a body region PB and a source region NS, described below. The body region PB and the source region NS are electrically connected to the source electrode SE via the hole CH1. In the outer peripheral region OR, the hole CH2 is formed on the gate electrode GE. The gate electrode GE is electrically connected to the gate wiring GW via the hole CH2.

A cross-sectional structure of the semiconductor device 100 will be described below with reference to FIG. 5.

As illustrated in FIG. 5, the semiconductor device 100 includes an n-type semiconductor substrate SUB having an upper surface TS and a lower surface BS. The semiconductor substrate SUB is made of n-type silicon. The semiconductor substrate SUB has an n-type drift region NV having a low concentration. In the first embodiment, the n-type semiconductor substrate SUB itself forms the drift region NV. The semiconductor substrate SUB may be a stacked body of an n-type silicon substrate and an n-type semiconductor layer grown on the n-type silicon substrate while being doped with phosphorus (P) by an epitaxial growing method. In the case, the n-type semiconductor layer having the low concentration forms the drift region NV, and the n-type silicon substrate having the high concentration forms a drain region ND.

The n-type drain region ND is formed in the semiconductor substrate SUB to reach a predetermined depth from the lower surface BS of the semiconductor substrate SUB toward the upper surface TS of the semiconductor substrate SUB. The drain region ND has a higher impurity concentration than that of the drift region NV. A drain electrode DE is formed on the lower surface BS of the semiconductor substrate SUB. The drain electrode DE is made of a single-layer metal film such as an aluminum film, a titanium film, a nickel film, a gold film, or a silver film or a stacked film obtained by appropriately stacking the metal films. The drain region ND and the drain electrode DE are formed over the cell region CR and the outer peripheral region OR. To the semiconductor substrate SUB (the drain region ND and the drift region NV), a drain potential is supplied from the drain electrode DE.

The plurality of trenches TR that reach a predetermined depth from the upper surface TS of the semiconductor substrate SUB toward the lower surface BS of the semiconductor substrate SUB are formed in the semiconductor substrate SUB.

As illustrated in the cross section A-A in FIG. 5, the field plate electrode FP is formed in the lower portion of the trench TR through an insulating film IF1 in the inner portion of the trench TR. A position of an upper surface of the insulating film IF1 is lower than a position of the upper surface of the field plate electrode FP.

A gate insulating film GI is formed in the inner portion of the trench TR on the insulating film IF1. An insulating film IF2 is formed to cover the field plate electrode FP exposed from the insulating film IF1. The gate electrode GE is formed over the field plate electrode FP through the insulating film IF2. The field plate electrode FP and the gate electrode GE are each made of, for example, a polycrystal silicon film doped with an n-type impurity. The impurity concentration of the polycrystal silicon film is higher than the impurity concentration of the semiconductor substrate SUB (the drift region NV).

A portion of the gate electrode GE is also formed in a space between the field plate electrode FP and the semiconductor substrate SUB and surrounded by the insulating film IF1, the insulating film IF2, and the gate insulating film GI.

The insulating film IF1 is formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. The semiconductor substrate SUB, the gate electrode GE, and the field plate electrode FP are electrically insulated from one another by the films. The insulating film IF1, the insulating film IF2, and the gate insulating film GI are each made of, for example, a silicon oxide film.

The p-type body region PB that reaches a predetermined depth from the upper surface TS of the semiconductor substrate SUB toward the lower surface BS of the semiconductor substrate SUB is formed in the semiconductor substrate SUB. The depth of the body region PB from the upper surface TS of the semiconductor substrate SUB is shallower than the depth of the trench TR from the upper surface TS of the semiconductor substrate SUB. The n-type source region NS is formed in the body region PB. The source region NS has a higher impurity concentration than that of the drift region NV.

An interlayer insulating film IL is formed on the upper surface TS of the semiconductor substrate SUB to cover the trench TR. The interlayer insulating film IL is made of, for example, a silicon oxide film.

The hole CH1 that penetrates the interlayer insulating film IL and the source region NS and reaches the body region PB is formed in the interlayer insulating film IL. A high-concentration diffusion region PR is formed in the body region PB in a bottom portion of the hole CH1. The high-concentration diffusion region PR has a higher impurity concentration than that of the body region PB. The high-concentration diffusion region PR is mainly provided to reduce a contact resistance with a plug PG and to prevent latch-up.

The source electrode SE is formed on the interlayer insulating film IL. The source electrode SE is electrically connected to the source region NS, the body region PB, and the high-concentration diffusion region PR via the hole CH1, and supplies a source potential to these impurity regions.

As illustrated in the cross section B-B in FIG. 5, a portion of the field plate electrode FP forms the pullout part FPa in the field plate electrode FP. A position on the upper surface of the insulating film IF1 being in contact with the pullout part FPa is higher than a position on the upper surface of the insulating film IF1 being in contact with the field plate electrode FP other than the pullout part FPa.

The insulating film IF2 is formed to cover the pullout part FPa exposed from the insulating film IF1. Although the body region PB is formed in the semiconductor substrate SUB adjacent to the pullout part FPa, the source region NS is not formed in this body region PB.

The hole CH3 that penetrates the interlayer insulating film IL and reaches the pullout part FPa is formed in the interlayer insulating film IL. The source electrode SE is electrically connected to the pullout part FPa via the hole CH3, and supplies a source potential to the field plate electrode FP.

The hole CH2 that penetrates the interlayer insulating film IL and reaches the gate electrode GE is formed in the interlayer insulating film IL, although not illustrated here. The gate wiring GW is electrically connected to the gate electrode GE via the hole CH2, and supplies a gate potential to the gate electrode GE.

The plug PG is embedded in each of the holes CH1, CH2, and CH3. The plug PG is made of, for example, a first barrier metal film and a first conductive film formed on the first barrier metal film. The first barrier metal film is made of, for example, a stacked film of a titanium film and a titanium nitride film. The first conductive film is, for example, a tungsten film.

Each of the source electrode SE and the gate wiring GW is made of, for example, a second barrier metal film and a second conductive film formed on the second barrier metal film. The second barrier metal film is, for example, a titanium tungsten film. The second conductive film is, for example, an aluminum alloy film to which copper or silicon is added.

### <Method of Manufacturing Semiconductor Device>

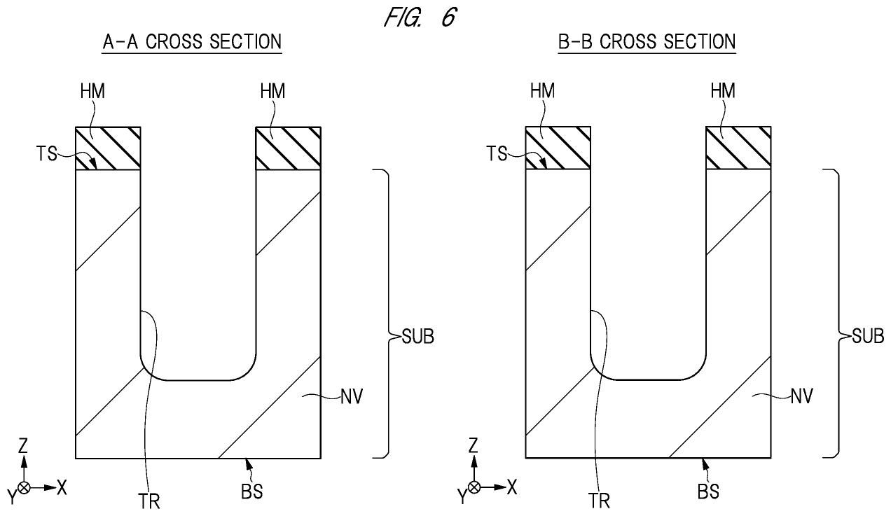

Manufacturing steps included in the method of manufacturing the semiconductor device 100 will be described below with reference to FIGS. 6 to 25.

As illustrated in FIG. 6, the n-type semiconductor substrate SUB having the upper surface TS and the lower surface BS is first prepared. As described above, the semiconductor substrate SUB may be a stacked body of the n-type silicon substrate and the n-type semiconductor layer formed on the silicon substrate by the epitaxial growing method.

Then, for example, the silicon oxide film is formed on the semiconductor substrate SUB by, for example, film formation process using a CVD (chemical vapor deposition) method. Then, the silicon oxide film is patterned to form a hard mask HM by a photolithography technique and anisotropic etching process. Then, anisotropic etching process is performed while using the hard mask HM as a mask to form the trench TR in the semiconductor substrate SUB to reach a predetermined depth from the upper surface TS of the semiconductor substrate SUB toward the lower surface BS of the semiconductor substrate SUB. Then, the hard mask HM is removed by, for example, isotropic etching process using a solution containing hydrofluoric acid.

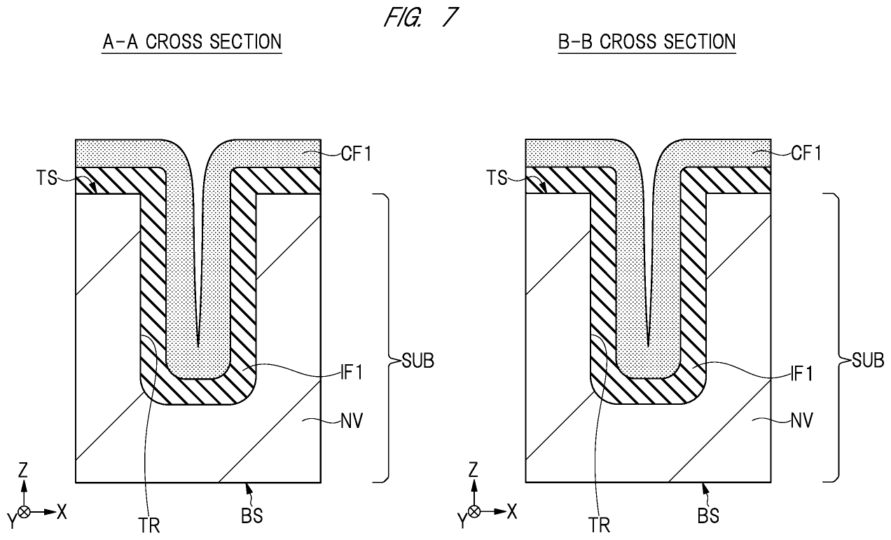

As illustrated in FIG. 7, the insulating film IF1 is first formed in the inner portion of the trench TR and on the upper surface TS of the semiconductor substrate SUB. The insulating film IF1 is, for example, a silicon oxide film formed by thermal oxidation process. The insulating film IF1 may be a stacked film of a first silicon oxide film formed by thermal oxidation process and a second silicon oxide film formed on the first silicon oxide film by film formation process using a CVD method.

Then, the conductive film CF1 is formed on the insulating film IF1 by, for example, film formation process using a CVD method. The conductive film CF1 is, for example, an n-type polycrystal silicon film.

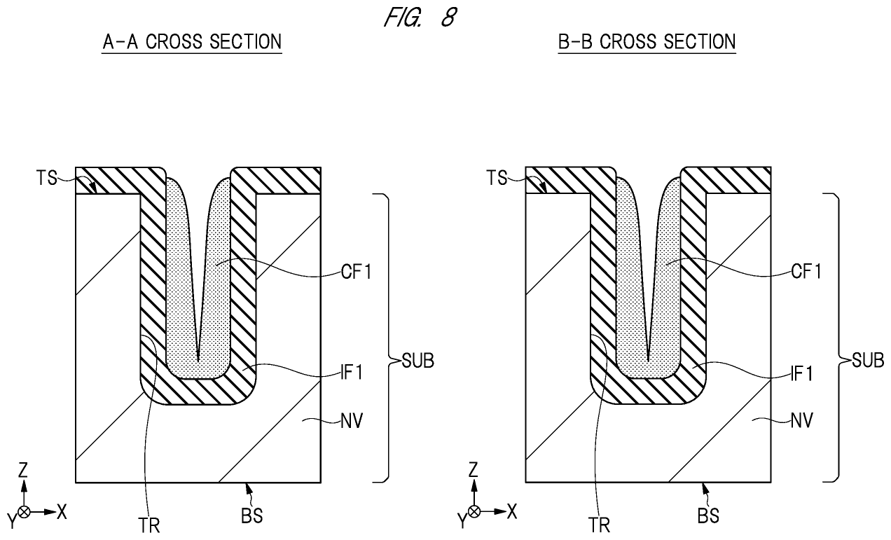

As illustrated in FIG. 8, by etching process, the thickness of the conductive film CF1 positioned in the inner portion of the trench TR is reduced, and the conductive film CF1 positioned in the outer portion of the trench TR is removed.

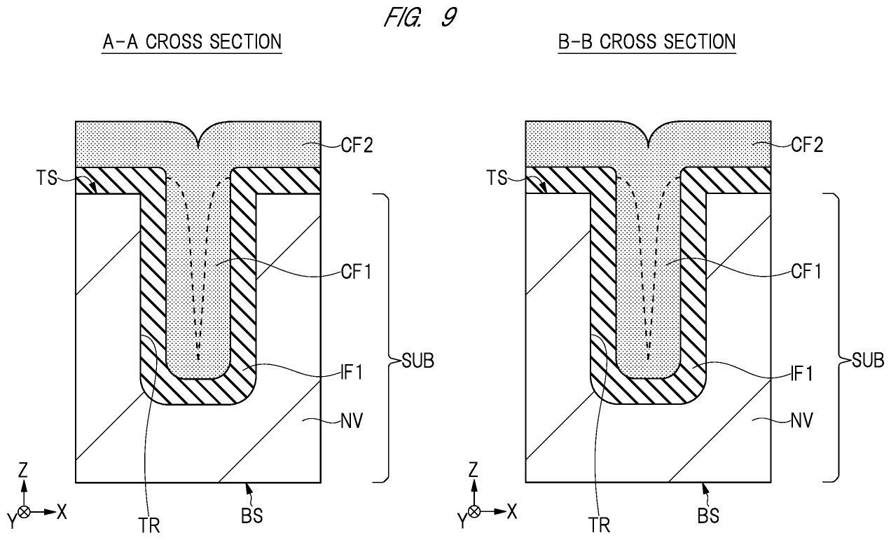

As illustrated in FIG. 9, the conductive film CF2 is formed on the insulating film IF1 and on the conductive film CF1 to fill the inner portion of the trench TR by, for example, film formation process using a CVD method. The conductive film CF2 is also formed on the insulating film IF1 in the outer portion of the trench TR. The conductive film CF2 is, for example, an n-type polycrystal silicon film. In the manufacturing step illustrated in FIG. 8, the thickness of the conductive film CF1 is made smaller as being closer to the uppermost portion of the trench TR. Accordingly, the conductive film CF2 can be formed in a state with a lower aspect ratio than that of a case without the conductive film CF1. Therefore, the inner portion of the trench TR is easily favorably filled with the conductive film CF2.

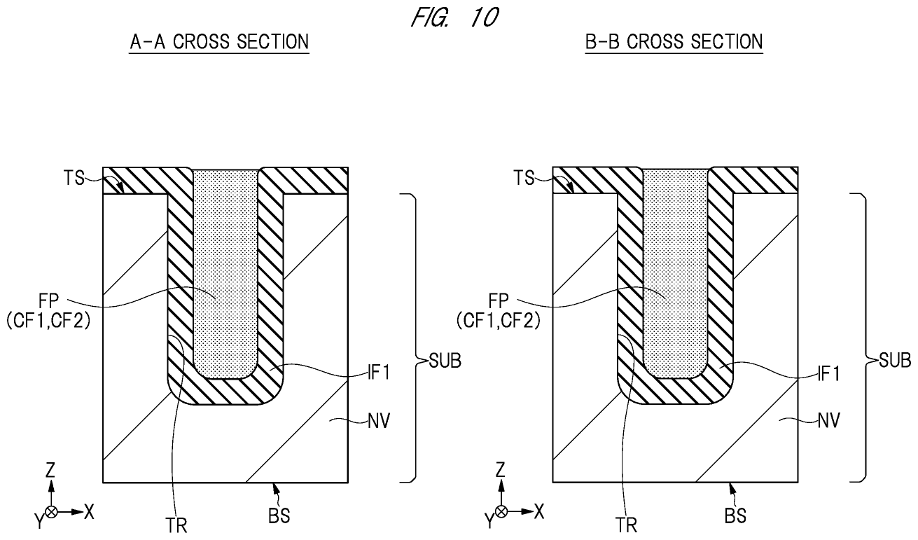

As illustrated in FIG. 10, the conductive film CF2 positioned in the outer portion of the trench TR is removed such that the conductive film CF1 and the conductive film CF2 are left in the inner portion of the trench TR by, for example, polishing process using a CMP (chemical mechanical polishing) method. The conductive film CF1 and the conductive film CF2 that are left in the inner portion of the trench TR form the field plate electrode FP. Thus, the field plate electrode FP is formed on the insulating film IF1 to fill the inner portion of the trench TR.

The field plate electrode FP can also be made of only the conductive film CF2. In the case, the conductive film CF1 is not formed, but the conductive film CF2 is formed on the insulating film IF1 to fill the inner portion of the trench TR. The conductive film CF2 positioned in the outer portion of the trench TR is removed such that the conductive film CF2 is left in the inner portion of the trench TR. The conductive film CF2 left in the inner portion of the trench TR forms the field plate electrode FP. This case can simplify the manufacturing process more than that in the case where the field plate electrode FP is made of the conductive film CF1 and the conductive film CF2.

However, the conductive film CF1 previously processed in a sidewall shape is preferably formed in the inner portion of the trench TR, as described in FIGS. 8 to 10, from the viewpoint of favorably filling the inner portion of the trench TR with the conductive film CF2.

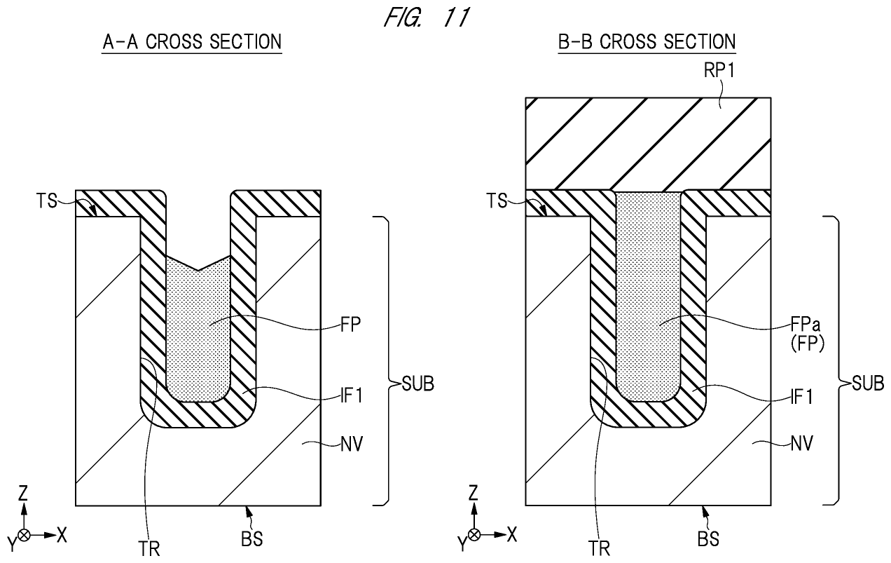

As illustrated in FIG. 11, the other portion of the field plate electrode FP is selectively recessed such that a portion of the field plate electrode FP is left as the pullout part FPa.

Specifically, a resist pattern RP1 that selectively covers a portion of the field plate electrode FP serving as the pullout part FPa is formed, as illustrated in a cross section B-B in FIG. 11. Then, etching process (etch-back process) such as dry etching or plasma etching using, for example, SF₆ gas is performed to the other portion of the field plate electrode FP not serving as the pullout part FPa while using the resist pattern RP1 as a mask. That is, the other portion of the field plate electrode FP exposed from the resist pattern RP1 is selectively recessed toward a bottom portion of the trench TR, as illustrated in a cross section A-A in FIG. 11. The portion of the field plate electrode FP that has not been recessed serves as the pullout part FPa.

As illustrated in FIG. 12, etching process (planarizing process) using, for example, mixed gas containing CF₄ gas and O₂ gas is performed to an upper surface of the field plate electrode FP. The upper surface of the field plate electrode FP is planarized by the etching process illustrated in FIG. 12. That is, the surface roughness of the upper surface of the field plate electrode FP after the etching process illustrated in FIG. 11 is reduced by the etching process illustrated in FIG. 12. Then, the resist pattern RP1 is removed by ashing process.

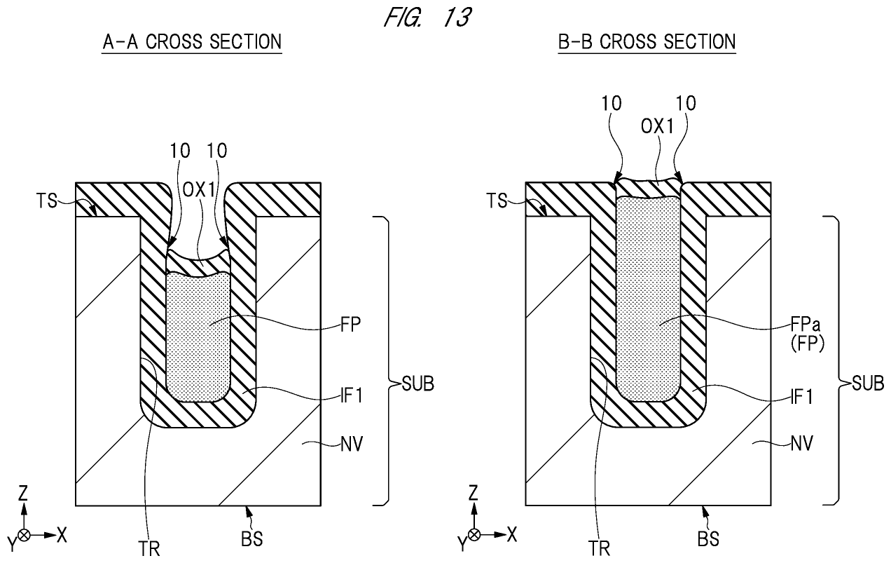

As illustrated in FIG. 13, a silicon oxide film OX1 is formed on the upper surface of the field plate electrode FP by thermal oxidation process. The thermal oxidation process is wet oxidation process, and is performed using, for example, water vapor. The thickness of the insulating film IF1 formed to be upper than the field plate electrode FP is increased by this thermal oxidation process.

An upper portion of the field plate electrode FP is rounded by this thermal oxidation process. The width of the upper portion of the field plate electrode FP in the X-direction decreases by the thickness of the silicon oxide film OX1.

The upper portion of the field plate electrode FP is a portion including the upper surface of the field plate electrode FP and a portion of a side surface of the field plate electrode FP connecting with the upper surface. In other words, the upper portion of the field plate electrode FP is a portion of the field plate electrode FP, the portion being exposed from the insulating film IF1.

FIG. 13 illustrates a starting point 10 of isotropic etching process to be performed to the insulating film IF1 and the silicon oxide film OX1. The etching in the isotropic etching process progresses toward an entire surface of the insulating film IF1 and the silicon oxide film OX1. The starting point 10 described here means a position finally largely affecting a shape of the insulating film IF1 in a portion being in contact with the field plate electrode FP.

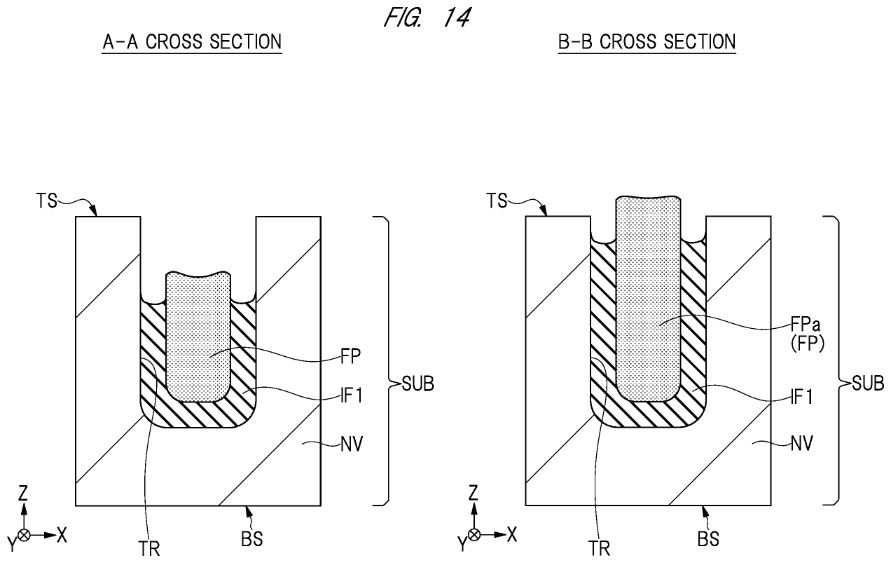

As illustrated in FIG. 14, the silicon oxide film OX1 and the insulating film IF1 positioned on the upper surface TS of the semiconductor substrate SUB are removed by isotropic etching process using a solution containing a hydrofluoric acid. At the same time, the insulating film IF1 positioned in the inner portion of the trench TR is recessed toward the bottom portion of the trench TR such that a position of an upper surface of the insulating film IF1 positioned in the inner portion of the trench TR is lower than a position of the upper surface of the field plate electrode FP in cross-sectional view. At the end of the isotropic etching process, the upper surface of the insulating film IF1 has a curved shape that more ascends as being closer to the semiconductor substrate SUB and more ascends as being closer to the field plate electrode FP.

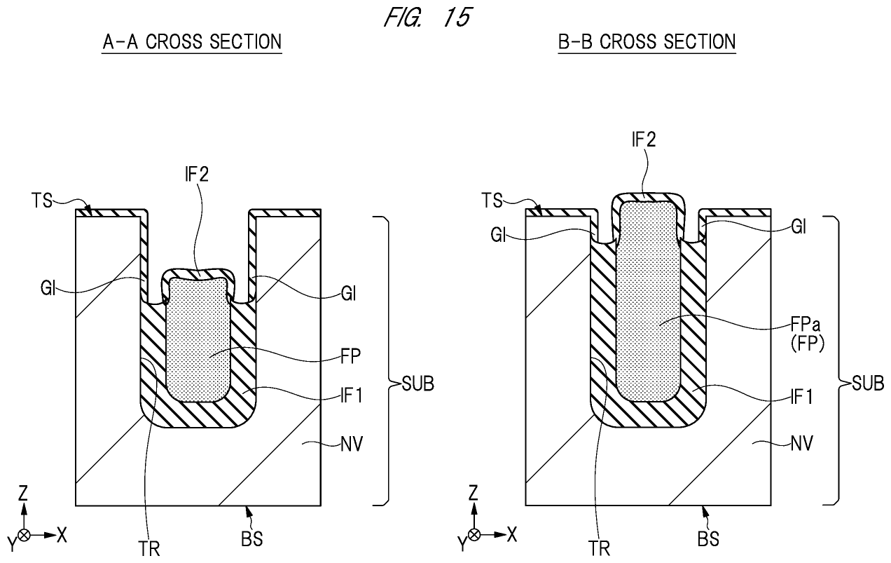

As illustrated in FIG. 15, by thermal oxidation process, a gate insulating film GI is formed on the upper surface TS of the semiconductor substrate SUB and in the inner portion of the trench TR positioned on the insulating film IF1 while an insulating film IF2 is formed to cover the field plate electrode FP exposed from the insulating film IF1.

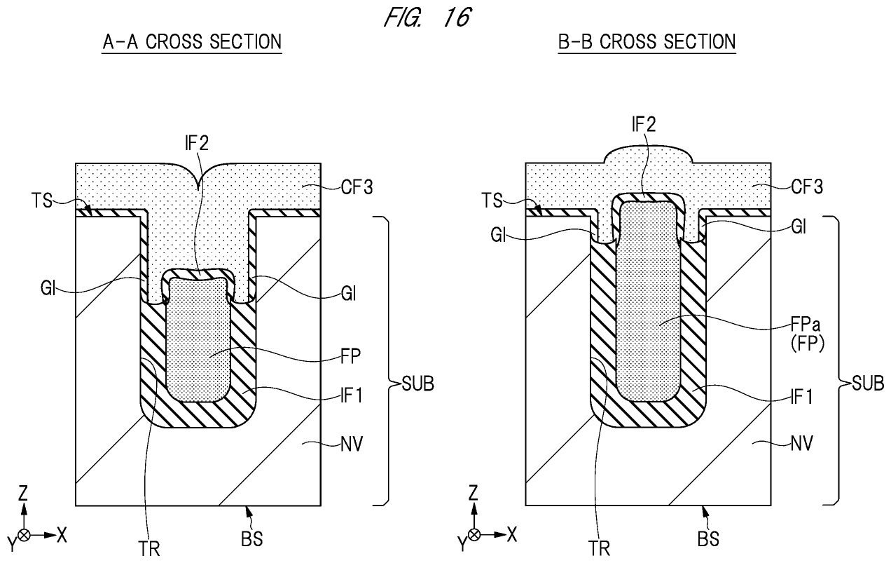

As illustrated in FIG. 16, a conductive film CF3 is formed on the gate insulating film GI, on the insulating film IF2, and on the insulating film IF1 to fill the inner portion of the trench TR by, for example, film formation process using a CVD method. The conductive film CF3 is, for example, an n-type polycrystal silicon film.

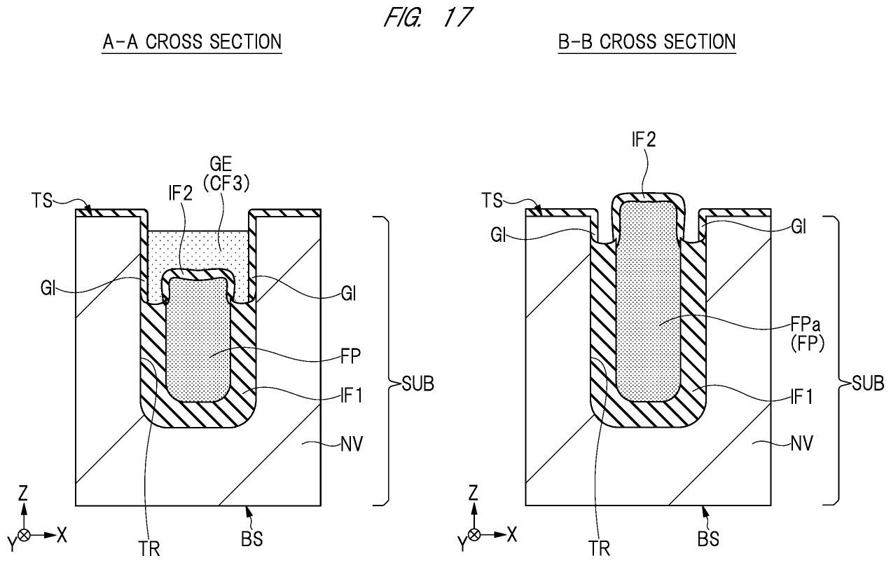

As illustrated in FIG. 17, first, polishing process using a CMP method is performed to the conductive film CF3. As a result, the thickness of the conductive film CF3 is reduced, and an upper surface of the conductive film CF3 is planarized. Then, anisotropic etching process is performed to the conductive film CF3 to remove the conductive film CF3 positioned in the outer portion of the trench TR. As a result, the conductive film CF3 left in the inner portion of the trench TR on the field plate electrode FP is formed as a gate electrode GE, as illustrated in a cross section A-A in FIG. 17.

In order to completely remove the conductive film CF3 positioned in the outer portion of the trench TR, overetching is performed for the anisotropic etching process. Accordingly, a position of an upper surface of the gate electrode GE is lower than the position of the upper surface TS of the semiconductor substrate SUB, as illustrated in the cross section A-A in FIG. 17. The conductive film CF3 formed on the insulating film IF2 and on the insulating film IF1 being in contact with the pullout part FPa is removed by the anisotropic etching process, as illustrated in a cross section B-B in FIG. 17.

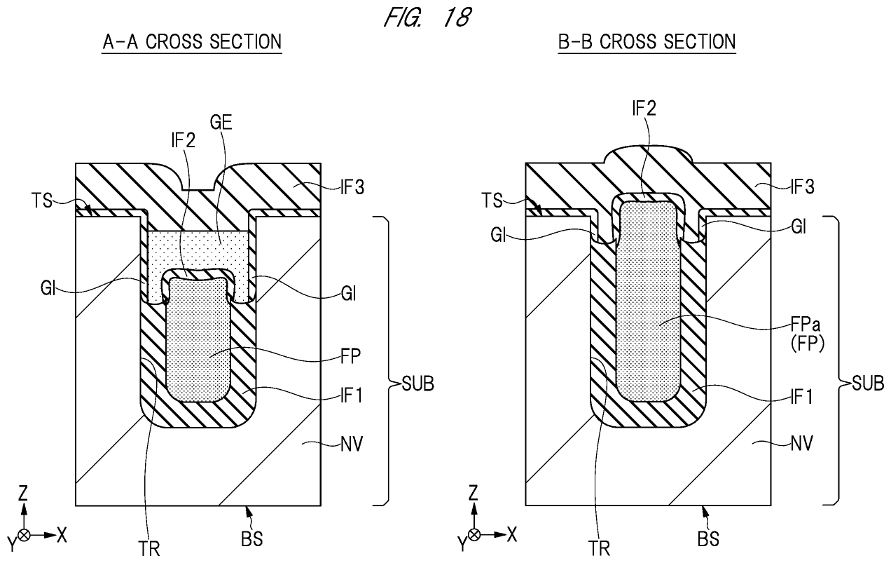

As illustrated in FIG. 18, an insulating film IF3 is formed on the gate insulating film GI, on the gate electrode GE, on the insulating film IF2, and on the insulating film IF1 to cover the trench TR by, for example, film formation process using a CVD method.

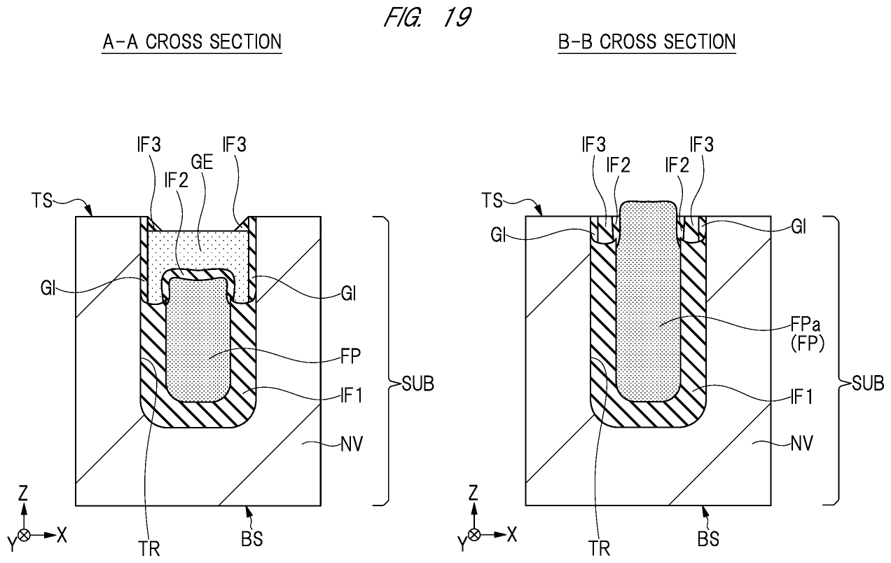

As illustrated in FIG. 19, anisotropic etching process is performed to the insulating film IF3. As a result, the insulating film IF3 and the gate insulating film GI on the upper surface TS of the semiconductor substrate SUB and the insulating film IF2 on the field plate electrode FP are removed. The insulating film IF3 is left on a portion of the gate electrode GE and on the insulating film IF1 being in contact with the pullout part FPa, as illustrated in FIG. 19.

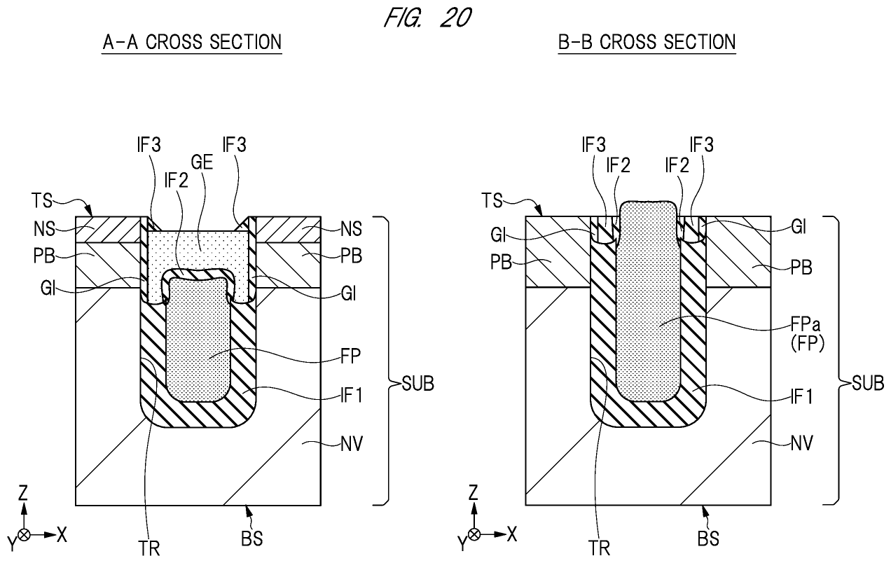

As illustrated in FIG. 20, first, the p-type body region PB is selectively formed in the semiconductor substrate SUB by a photolithography technique and an ion implantation method for doping with an impurity such as boron (B). The body region PB is formed such that the depth itself from the upper surface TS of the semiconductor substrate SUB is shallower than the depth of the trench TR.

Then, the n-type source region NS is selectively formed in the body region PB in the cell region CR by a photolithography technique and an ion implantation method for doping with an impurity such as arsenic (As), as illustrated in a cross section A-A in FIG. 20. The source region NS is not formed in the body region PB adjacent to the pullout part FPa, as illustrated in a cross section B-B in FIG. 20. Then, heat process is performed to the semiconductor substrate SUB to activate the impurities contained in the source region NS and the body region PB.

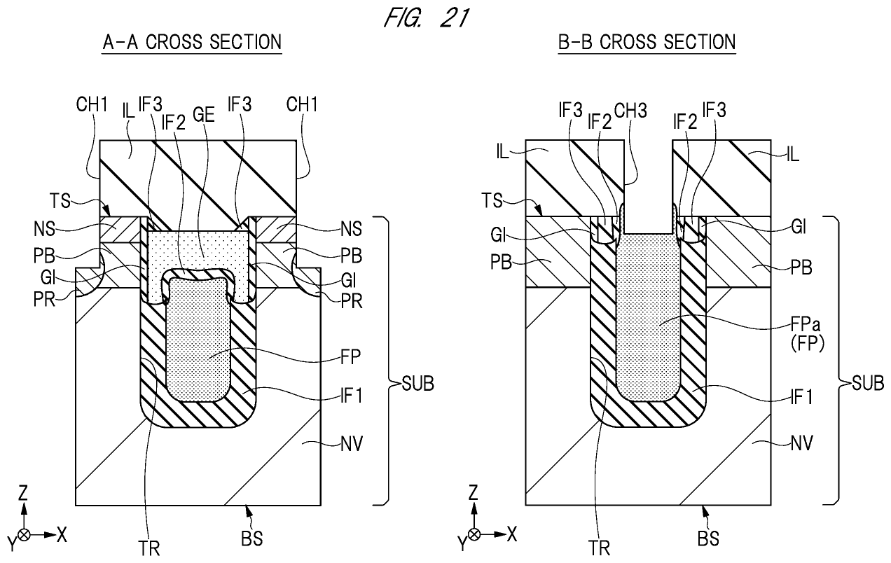

As illustrated in FIG. 21, first, the interlayer insulating film IL is formed on the upper surface TS of the semiconductor substrate SUB to cover the trench TR by, for example, a CVD method.

Then, the holes CH1, CH2, and CH3 are formed in the interlayer insulating film IL. Specifically, first, a resist pattern having a pattern for opening the upper portion of the source region NS is formed on the interlayer insulating film IL. Then, anisotropic etching process is performed while using the resist pattern as a mask to form the hole CH1 that penetrates the interlayer insulating film IL and the source region NS and reaches the inside of the body region PB. Then, the body region PB in the bottom portion of the hole CH1 is doped with the impurity such as boron (B) by an ion implantation method to form the p-type high-concentration diffusion region PR. Then, the resist pattern is removed by ashing process.

Then, a resist pattern having a pattern for opening the upper portion of the pullout part FPa and the upper portion of the gate electrode GE is formed on the interlayer insulating film IL. Then, anisotropic etching process is performed while using the resist pattern as a mask to form the hole CH3 that penetrates the interlayer insulating film IL and reaches the pullout part FPa. The hole CH2 is also formed by the manufacturing step of forming the hole CH3, although not illustrated here. The hole CH2 penetrates the interlayer insulating film IL and reaches the gate electrode GE. Then, the resist pattern is removed by ashing process.

Either the formation of the hole CH1 or the formation of the hole CH2 and the hole CH3 can be performed first.

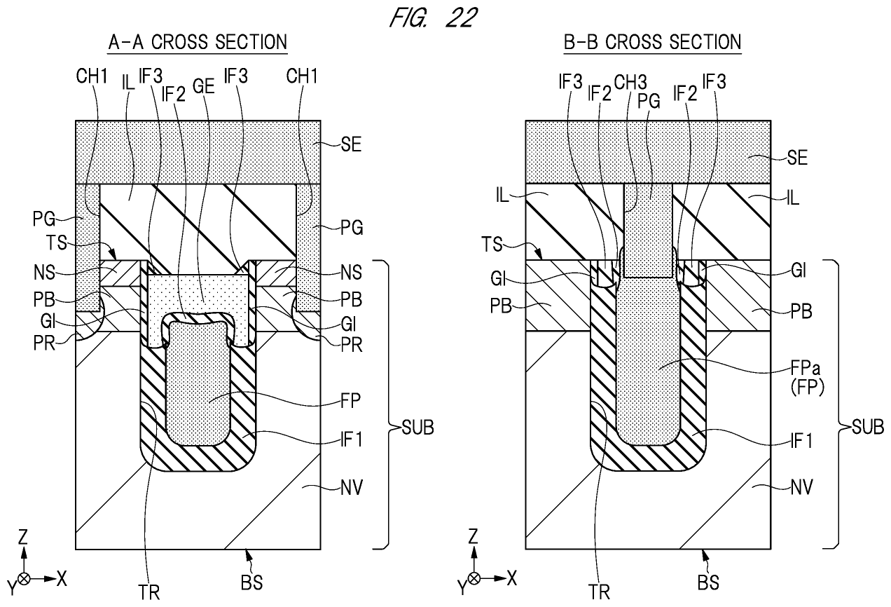

As illustrated in FIG. 22, a plug PG is formed in each of the holes CH1, CH2, and CH3, and the source electrode SE and the gate wiring GW are formed on the interlayer insulating film IL.

First, the first barrier metal film is formed in each of the holes CH1, CH2, and CH3 and on the interlayer insulating film IL by film formation process using a sputtering method or a CVD method. The first barrier metal film is made of, for example, a stacked film of a titanium nitride film and a titanium film. Then, the first conductive film is formed on the first barrier metal film by film formation process using a CVD method. The first conductive film is made of, for example, a tungsten film. Then, the first barrier metal film and the first conductive film in the outer portion of each of the holes CH1, CH2, and CH3 are removed by polishing process using a CMP method or anisotropic etching process. As a result, the plug PG made of the first barrier metal film and the first conductive film is formed to fill the inner portion of each of the holes CH1, CH2, and CH3.

Then, the second barrier metal film is formed on the interlayer insulating film IL by film formation process using a sputtering method. The second barrier metal film is made of, for example, a titanium tungsten film. Then, the second conductive film is formed on the second barrier metal film by film formation process using a sputtering method. The second conductive film is, for example, an aluminum alloy film to which copper or silicon is added. Then, the second barrier metal film and the second conductive film are patterned to form the source electrode SE and the gate wiring GW.

Then, the protective film made of, for example, a polyimide film is formed on the source electrode SE and the gate wiring GW by, for example, a coating method, although not illustrated here. The opening is formed in a portion of the protective film to expose respective regions of the source electrode SE and the gate wiring GW, the regions serving as the source pad SP and the gate pad GP.

Then, the structure illustrated in FIG. 5 is obtained through the following manufacturing steps. First, the lower surface BS of the semiconductor substrate SUB is polished, as needed. Then, the lower surface BS of the semiconductor substrate SUB is doped with, for example, arsenic (As) by an ion implantation method to form the n-type drain region ND. When the semiconductor substrate SUB is made of the stacked body of the n-type silicon substrate and the n-type semiconductor layer, the n-type silicon substrate having the high concentration serves as the drain region ND. Accordingly, formation of the drain region ND by the ion implantation as described above can be omitted. Then, the drain electrode DE is formed on the lower surface BS of the semiconductor substrate SUB by film formation process using a sputtering method.

### <Thermal Oxidation Process in FIG. 13>

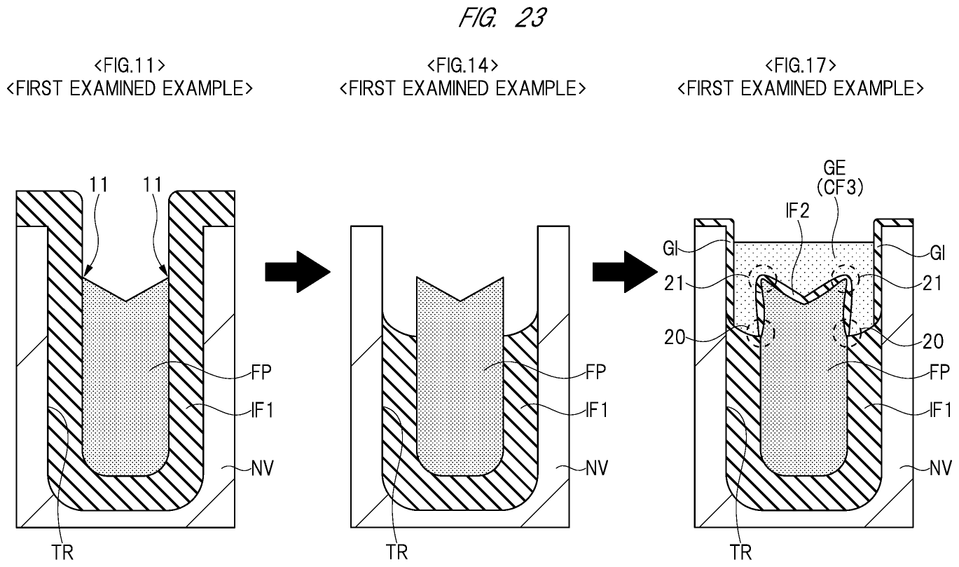

The reason why the thermal oxidation process illustrated in FIG. 13 is performed will be described below with reference to FIG. 23 in comparison with a first examined example. Problems described in the first examined example are not publicly-known knowledge but knowledge newly obtained by the inventors of the present application.

FIG. 23 illustrates the step of recessing the field plate electrode FP illustrated in FIG. 11, the step of recessing the insulating film IF1 illustrated in FIG. 14, and the step of forming the gate electrode GE illustrated in FIG. 17. In the first examined example, the etching step on the upper surface of the field plate electrode FP as described in FIG. 12 and the formation of the silicon oxide film OX1 by the thermal oxidation process as described in FIG. 13 are not performed.

As illustrated in FIG. 23, in the first examined example, an isotropic etching step on the insulating film IF1 starts from a starting point 11. Therefore, a position of a portion of the upper surface of the insulating film IF1 positioned in the inner portion of the trench TR, the portion being in contact with the field plate electrode FP, is recessed more downward than a position of a portion of the same being in contact with a side portion of the semiconductor substrate SUB. Then, when the gate insulating film GI and the insulating film IF2 are formed while the gate electrode GE is formed from the conductive film CF3, a shape of a lower end of the gate electrode GE tends to protrude in the vicinity of the recessed insulating film IF1. An electric field tends to be concentrated on such a protruding portion.

FIG. 23 illustrates a risk portion 20 as a portion on which the electric field tends to be concentrated. Further, oxygen gas is difficult to be supplied to the vicinity of the risk portion 20, and the thickness of the insulating film IF2 tends to be locally thin. Therefore, the first examined example has a problem that is difficulty in securement of a withstand voltage between the gate electrode GE and the field plate electrode FP in the risk portion 20.

When an upper portion of the field plate electrode FP has a protrusion shape, such a protruding portion is also a risk portion 21 on which the electric field tends to be concentrated. There is a problem that is difficulty in securement of the withstand voltage between the gate electrode GE and the field plate electrode FP even in the risk portion 21.

In the first embodiment, by the thermal oxidation process illustrated in FIG. 13, the silicon oxide film OX1 is formed on the upper surface of the field plate electrode FP. Accordingly, the isotropic etching process to be performed on the insulating film IF1 and the silicon oxide film OX1 starts from the starting point 10 that is a higher position than the starting point 11 in the first examined example.

As a result, when the isotropic etching process illustrated in FIG. 13 is finished, the upper surface of the insulating film IF1 has a curved shape that more ascends as being closer to the semiconductor substrate SUB and more ascends as being closer to the field plate electrode FP, as illustrated in FIG. 14.

When film formation process using a CVD method is applied to the formation of the insulating film IF1, an etching rate at the time of the isotropic etching step is higher on the CVD film than the thermal oxidation process film, and therefore, it is easier to form the above-described curved shape. Then, even if the gate electrode GE is formed from the conductive film CF₃, the shape of the lower end of the gate electrode GE does not protrude, as illustrated in the cross section A-A in FIG. 17. Accordingly, the concentration of the electric field on the risk portion 20 in the first examined example is reduced.

Even if the thickness of the insulating film IF2 in the vicinity of the insulating film IF1 is small, the thickness can be compensated by the insulating film IF1. Therefore, the withstand voltage can be secured between the gate electrode GE and the field plate electrode FP, and the reliability of the semiconductor device 100 can be improved.

The upper portion of the field plate electrode FP is rounded by the thermal oxidation process illustrated in FIG. 13. Accordingly, the concentration of the electric field on the risk portion 21 in the first examined example is reduced. Even on the risk portion 21, the withstand voltage between the gate electrode GE and the field plate electrode FP can also be secured.

### <Etching Process in FIG. 12>

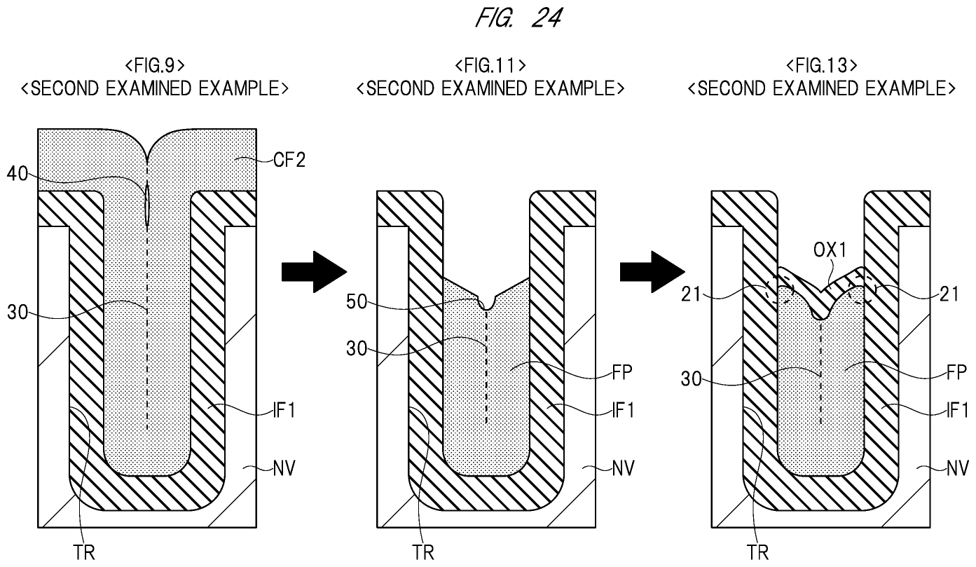

The reason why the etching process illustrated in FIG. 12 is performed will be described below with reference to FIGS. 24 to 26 in comparison with a second examined example. Problems illustrated in the second examined example are not publicly-known knowledge but knowledge newly found by the inventors of the present application.

FIG. 24 illustrates the step of forming the conductive film CF2 illustrated in FIG. 9, the step of recessing the field plate electrode FP illustrated in FIG. 11, and the step of forming the silicon oxide film OX1 illustrated in FIG. 13. In the second examined example, the etching step on the upper surface of the field plate electrode FP as described in FIG. 12 is not performed.

As illustrated in FIG. 24, the formation of the conductive film CF2 starts from both side surfaces of the trench TR in the X-direction, and is closed in the vicinity of the center of the trench TR. FIG. 24 illustrates a closed interface as a seam surface 30 of the conductive film CF2. Voids 40 tend to occur in the vicinity of the center of the trench TR due to the shape of the trench TR and the aspect ratio at the time of film formation of the conductive film CF2. The seam surface 30 has weak interatomic bond, and may be affected by the surface roughness of the conductive film CF2 to intermittently form small voids.

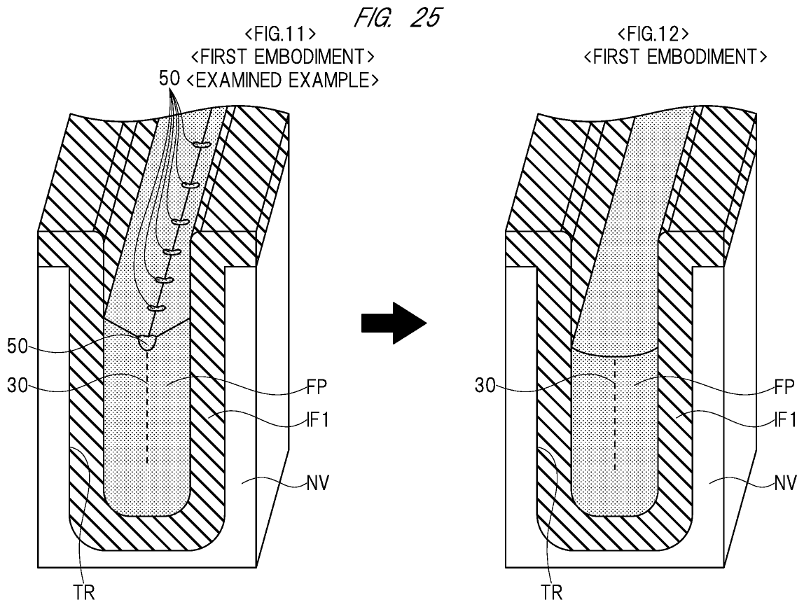

On the voids 40 and the seam surface 30, the etching rate at the anisotropic etching process illustrated in FIG. 11 tends to be higher than that on other portions of the conductive film CF2. Accordingly, as illustrated in FIGS. 24 and 25, a divot (recess) 50 tends to be formed in the conductive film CF2 in the vicinity of the center of the trench TR at the time of the anisotropic etching process illustrated in FIG. 11.

When the thermal oxidation process illustrated in FIG. 13 is performed in this state to form the silicon oxide film OX1, the oxidation progresses into the field plate electrode FP from the divot 50 as a starting point. Accordingly, the shape of the upper portion of the field plate electrode FP tends to protrude, and the risk portion 21 as described in the first examined example tends to occur. Therefore, there is a problem that is difficulty in the securement of the withstand voltage between the gate electrode GE and the field plate electrode FP. When the oxidation progresses into the field plate electrode FP from the divot 50 as the starting point as described above, a stress is laterally applied by volume expansion at the time of the oxidation, thereby causing a risk of a crystal defect in the semiconductor substrate SUB between the trenches TR.

In the subsequent manufacturing step, the silicon oxide film OX1 is removed in the upper portion of the field plate electrode FP, and the insulating film IF2 is formed. At this stage, the insulating film IF2 more deeply intrudes into the field plate electrode FP, and therefore, it is more difficult to secure the withstand voltage of the risk portion 21.

In the first embodiment, the etching process illustrated in FIG. 12 is performed to the upper surface of the field plate electrode FP before the silicon oxide film OX1 is formed, as illustrated in FIG. 25. The upper surface of the field plate electrode FP is planarized by the etching process illustrated in FIG. 12, and therefore, the thermal oxidation process illustrated in FIG. 13 can be performed in a state with removal of the divot 50.

The etching process illustrated in FIG. 12 is performed while using, for example, the mixed gas containing the CF₄ gas and the O₂ gas, and is performed without applying a bias potential.

The etching process illustrated in FIG. 11 and the etching process illustrated in FIG. 12 are performed while using a plasma process apparatus having a stage for mounting the semiconductor substrate SUB, although not illustrated. In the plasma process apparatus, atoms or molecules in processing gas are excited, ionized, or dissociated, thereby producing a plasma. Normally, when the plasma is produced, high-frequency power is supplied from a high-frequency power supply to the stage. As a result, the bias potential is formed above the semiconductor substrate SUB, and charged particles such as ions in the plasma are attracted to the semiconductor substrate SUB (there is the bias potential).

However, the etching process illustrated in FIG. 12 is performed in a state in which the semiconductor substrate SUB is mounted on the stage but in which no high-frequency power is supplied to the stage (there is no bias potential). The etching process illustrated in FIG. 11 is performed in a state in which the semiconductor substrate SUB is mounted on the stage and in which the high-frequency power supplied to the stage (there is the bias potential).

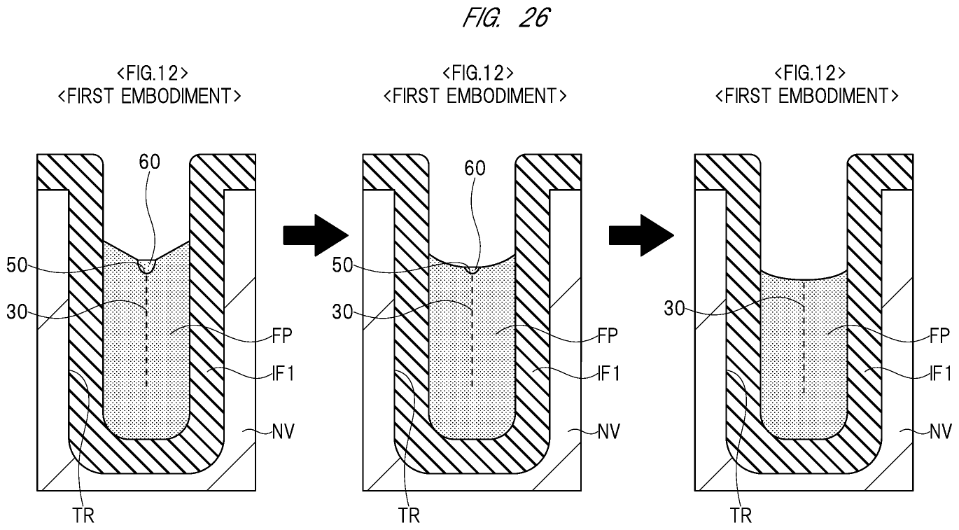

As illustrated in FIG. 26, when the etching process illustrated in FIG. 12 is started, a reaction product 60 such as SiOF is produced. In the etching process, the etching on the field plate electrode FP and on the reaction product 60 and the production of the reaction product 60 are repeated. Since the etching rate on the field plate electrode FP is higher than an etching rate on the reaction product 60, the reaction product 60 deposited in the divot 50 functions as a mask.

When the etching process is continued in the state, the field plate electrode FP exposed from the reaction product 60 is preferentially etched. When the etching process is further continued so that the field plate electrode FP is etched to substantially the same position as the depth position of the divot 50, the upper surface of the field plate electrode FP is planarized, a deposition distribution of the reaction product 60 is made uniform, and the progress of etching is delayed. Then, the reaction product 60 is removed by cleaning process, and the etching process ends. In the above-described cleaning process, for example, a solution containing a sulfuric acid and a solution containing ammonia and a hydrogen peroxide solution are used.

Thus, it can also be said that the etching process illustrated in FIG. 12 is chemical dry etching process using the reaction product 60.

The divot 50 can be removed by the etching process illustrated in FIG. 12 even if the divot 50 has been formed on the upper surface of the field plate electrode FP by the etching process illustrated in FIG. 11. That is, the surface roughness of the upper surface of the field plate electrode FP after the etching process illustrated in FIG. 11 is reduced by the etching process illustrated in FIG. 12.

Accordingly, the problem that is the intrusion of the oxidation into the field plate electrode FP from the divot 50 the starting point can be suppressed. Further, the upper surface of the field plate electrode FP is planarized, and the upper portion of the field plate electrode FP is rounded. Therefore, it is difficult to form the risk portion 21, and therefore, the withstand voltage between the gate electrode GE and the field plate electrode FP can be secured, and the reliability of the semiconductor device 100 can be improved.

When the ratio of the O₂ gas is made high, the production of the reaction product 60 can be promoted. Therefore, in the etching process illustrated in FIG. 12, the ratio of the O₂ gas contained in the mixed gas is preferably higher than the ratio of the CF₄ gas contained in the mixed gas.

In order to promote the production of the reaction product 60, the etching process illustrated in FIG. 12 is preferably performed at a temperature as low as possible.

In the etching process using the mixed gas containing the CF₄ gas and the O₂ gas having the feature with the high ratio of the O₂ gas, the etching rate on the field plate electrode FP is relatively low, and (etch) selectivity to a silicon oxide film such as the insulating film IF1 is not high, either. Therefore, only by, for example, the etching process illustrated in FIG. 12, it difficult to secure the thickness of the insulating film IF1 and secure the recession amount of the field plate electrode FP illustrated in FIG. 11.

The etching rate on the field plate electrode FP at the time of the etching process illustrated in FIG. 11 is higher than the etching rate on the field plate electrode FP at the time of the etching process illustrated in FIG. 12. In the etching process illustrated in FIG. 11, the etch selectivity to the insulating film IF1 is also higher than that in the etching process illustrated in FIG. 12. Therefore, most of the recession of the field plate electrode FP is preferably performed by the etching process illustrated in FIG. 11.

The etching process illustrated in FIG. 12 can be performed as substantial chemical dry etching process if there is no bias potential. Accordingly, it is unnecessary after the etching process illustrated in FIG. 11 to change the apparatus to another plasma process apparatus for the chemical dry etching process. The etching process illustrated in FIG. 11 and the etching process illustrated in FIG. 12 can be continuously performed in the same plasma process apparatus, and therefore, throughput can be reduced.

### Modification Example

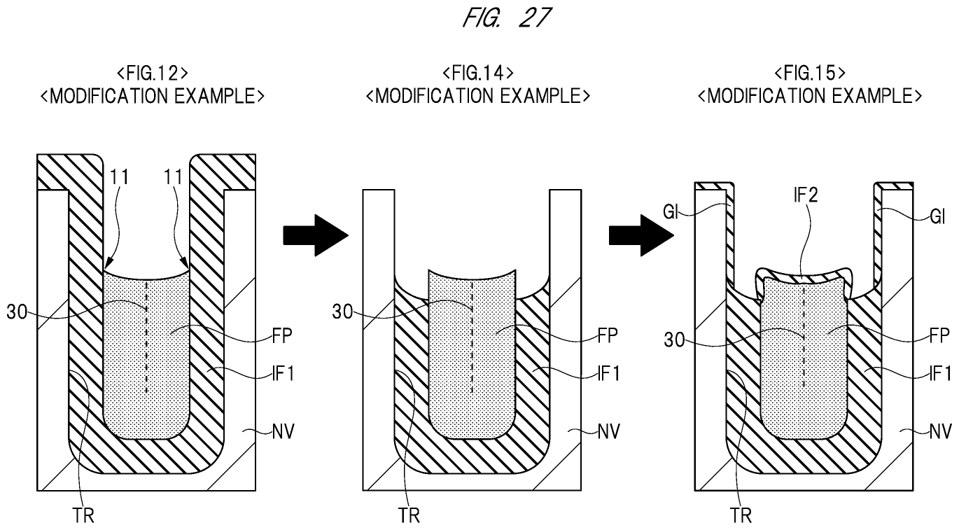

A modification example of the first embodiment will be described below with reference to FIG. 27.

In the modification example, the formation of the silicon oxide film OX1 illustrated in FIG. 13 may be omitted. In the case, a manufacturing step next to the etching process illustrated in FIG. 12 is the isotropic etching process illustrated in FIG. 14, as illustrated in FIG. 27. Accordingly, the modification example cannot provide the effect produced by the isotropic etching process from the starting point 10 that is the higher position than the starting point 11 and the effect produced by rounding the upper portion of the field plate electrode FP in the first examined example.

However, in the modification example, the etching process illustrated in FIG. 12 is performed to the upper surface of the field plate electrode FP as similar to the first embodiment. Accordingly, the problem that is the intrusion of the insulating film IF2 into the field plate electrode FP from the divot 50 as the starting point at the time of the thermal oxidation process illustrated in FIG. 15 can be suppressed. By the etching process illustrated in FIG. 12, the upper surface of the field plate electrode FP is planarized, and the upper portion of the field plate electrode FP is rounded. Accordingly, it is difficult to form the risk portion 21.

Therefore, in the modification example, the withstand voltage between the gate electrode GE and the field plate electrode FP can be more secured, and the reliability of the semiconductor device 100 can be more improved than those in the first and second examined examples. The manufacturing steps can be more simplified than those in the first embodiment because the formation of the silicon oxide film OX1 illustrated in FIG. 13 is omitted.

In the foregoing, the invention made by the inventors of the present application has been concretely described on the basis of the embodiments. However, the present invention is not limited to the foregoing embodiments, and various modifications can be made within the scope of the present invention.

What is claimed is:

1. A method of manufacturing a semiconductor device comprising steps of:
(a) preparing a semiconductor substrate having an upper surface and a lower surface;
(b) after the step (a), forming a trench in the semiconductor substrate to reach a predetermined depth from the upper surface of the semiconductor substrate toward the lower surface of the semiconductor substrate;
(c) after the step (b), forming a first insulating film in an inner portion of the trench and on the upper surface of the semiconductor substrate;
(d) after the step (c), forming a field plate electrode on the first insulating film to fill the inner portion of the trench;
(e) after the step (d), recessing the field plate electrode toward a bottom portion of the trench by etching process;
(f) after the step (e), performing etching process using mixed gas containing CF₄ gas and O₂ gas to an upper surface of the field plate electrode; and
(g) after the step (f), forming a first silicon oxide film on the upper surface of the field plate electrode by first thermal oxidation process.

2. The method of manufacturing the semiconductor device according to claim 1,
wherein a ratio of the O₂ gas contained in the mixed gas is higher than a ratio of the CF₄ gas contained in the mixed gas.

3. The method of manufacturing the semiconductor device according to claim 1,
wherein the etching process in the step (f) is performed while using a first plasma process apparatus having a stage for mounting the semiconductor substrate, and
wherein the etching process in the step (f) is performed in a state in which the semiconductor substrate is mounted on the stage and in which high-frequency power is not supplied to the stage.

4. The method of manufacturing the semiconductor device according to claim 3,
wherein the etching process in the step (e) is performed while using the first plasma process apparatus,
wherein the etching process in the step (e) is performed in a state in which the semiconductor substrate is mounted on the stage and in which the high-frequency power is supplied to the stage, and
wherein an etching rate on the field plate electrode in the etching process in the step (e) is higher than an etching rate on the field plate electrode in the etching process in the step (f).

5. The method of manufacturing the semiconductor device according to claim 4,
wherein SF₆ gas is used in the etching process in the step (e).

6. The method of manufacturing the semiconductor device according to claim 1,
wherein a surface roughness of the upper surface of the field plate electrode after the step (e) is reduced by the step (f).

7. The method of manufacturing the semiconductor device according to claim 1,
wherein the step (d) includes steps of:
(d1) after the step (c), forming a first conductive film on the first insulating film by first film formation process using a CVD method,
(d2) after the step (d1), reducing a thickness of the first conductive film positioned in the inner portion of the trench and removing the first conductive film positioned in an outer portion of the trench,
(d3) after the step (d2), forming a second conductive film on the first insulating film and on the first conductive film to fill the inner portion of the trench by second film formation process using a CVD method, and
(d4) after the step (d3), removing the second conductive film positioned in the outer portion of the trench such that the first conductive film and the second conductive film are left in the inner portion of the trench,
wherein in the step (d4), the first conductive film and the second conductive film left in the inner portion of the trench form the field plate electrode.

8. The method of manufacturing the semiconductor device according to claim 1,
wherein the step (d) includes steps of:
(d5) after the step (c), forming a second conductive film on the first insulating film to fill the inner portion of the trench by film formation process using a CVD method, and
(d6) after the step (d5), removing the second conductive film positioned in an outer portion of the trench such that the second conductive film is left in the inner portion of the trench,
wherein in the step (d6), the second conductive film left in the inner portion of the trench forms the field plate electrode.

9. The method of manufacturing the semiconductor device according to claim 1, further comprising steps of
(h) after the step (g), removing the first silicon oxide film and the first insulating film positioned on the upper surface of the semiconductor substrate, and recessing the first insulating film positioned in the inner portion of the trench toward the bottom portion of the trench such that a position of an upper surface of the first insulating film positioned in the inner portion of the trench is lower than a position of the upper surface of the field plate electrode,
(i) after the step (h), forming a gate insulating film in the inner portion of the trench positioned on the first insulating film and forming a second insulating film to cover the field plate electrode exposed from the first insulating film by second thermal oxidation process,
(j) after the step (i), forming a third conductive film on the gate insulating film, on the second insulating film, and on the first insulating film to fill the inner portion of the trench, and
(k) after the step (j), removing the third conductive film positioned in an outer portion of the trench, to form the third conductive film left in the inner portion of the trench on the field plate electrode as a gate electrode.

10. The method of manufacturing the semiconductor device according to claim 1, further comprising steps of:
(l) between the step (f) and the step (g), removing the first insulating film positioned on the upper surface of the semiconductor substrate and recessing the first insulating film positioned in the inner portion of the trench toward the bottom portion of the trench such that a position of an upper surface of the first insulating film positioned in the inner portion of the trench is lower than a position of the upper surface of the field plate electrode;
(m) after the step (l), forming a gate insulating film in the inner portion of the trench positioned on the first insulating film and forming the first silicon oxide film to cover the field plate electrode exposed from the first insulating film, by the first thermal oxidation process of the step (g);
(n) after the step (m), forming a third conductive film on the gate insulating film, on the first silicon oxide film, and on the first insulating film to fill the inner portion of the trench; and
(o) after the step (n), removing the third conductive film positioned in an outer portion of the trench to form the third conductive film left in the inner portion of the trench on the field plate electrode as a gate electrode.
